(19) United States
(12) Patent Application Publication
(10) Pub. No.: US 2016/0035869 A1
(43) Pub. Date: Feb. 4, 2016

(54) SEMICONDUCTOR DEVICE

(71) Applicant: KABUSHIKI KAISHA TOSHIBA, Tokyo (JP)

(72) Inventors: Tomoko MATSUDAI, Tokyo (JP); Tsuneo OGURA, Kanagawa (JP)

(21) Appl. No.: 14/813,910

(22) Filed: Jul. 30, 2015

Related U.S. Application Data
(62) Division of application No. 13/680,849, filed on Nov. 19, 2012, now abandoned.

(30) Foreign Application Priority Data
Mar. 15, 2012 (JP) 2012-059479

(51) Int. Cl. H01L 29/739; H01L 29/06; H01L 29/417; H01L 27/06; H01L 29/45; H01L 29/66; H01L 29/861; H01L 29/10; H01L 29/08

(52) U.S. Cl. CPC H01L 29/7397; H01L 29/1004; H01L 29/0649; H01L 29/417; H01L 29/0821; H01L 29/41708; H01L 29/45; H01L 29/66348; H01L 29/861; H01L 29/6609; H01L 27/0629; H01L 27/0623; H01L 29/0804

(57) ABSTRACT

A semiconductor device formed on a substrate of a first conductivity type, including a base layer of a second conductivity disposed on a first face of the substrate, an anode layer with a higher dopant amount in a portion of the base layer, an IGBT region formed on the base layer, a diode region formed on the anode layer, a trench extending from the top of the IGBT and diode regions in to the substrate. The area occupied by the diode region is different from the area occupied by the IGBT region, but they share collector and emitter electrodes. The contact area between the diode anode layer and the emitter electrode may be adjusted by the arrangement of trenches.

### CROSS-REFERENCE TO RELATED APPLICATION

This application is a division of U.S. patent application Ser. No. 13/680,849, filed on Nov. 19, 2012, which is based upon and claims the benefit of priority from Japanese Patent Application No. 2012-059479, filed Mar. 15, 2012; the entire contents of each of which are incorporated herein by reference.

### FIELD

Embodiments described herein relate to a semiconductor device.

### BACKGROUND

Recent history has seen the integration of insulated gate bipolar transistors (IGBT) and diodes in one body on a semiconductor substrate, the development of the reverse conducting insulated gate bipolar transistor (RC-IGBT), and a recognition of applications for both IGBT and RC-IGBT devices.

Conventionally, for example, an inverter circuit for supplying electricity to an inductive motor or the like, by conversion of direct current to alternating current is formed by using multiple IGBT units and multiple diodes. When a RC-IGBT is used, and since the IGBT and the diode can be formed in a single body there is a decrease in the area required in conventional systems. As such, there is generally a unit cost reduction, an improvement in the dispersion of by-product heat accompanying device usage, and other improvements over the conventional systems.

### DESCRIPTION OF THE DRAWINGS

FIG. 1 is a planar diagram of a semiconductor device according to a first embodiment.

FIG. 2 is a cross-sectional diagram showing the cross section at the A-A′ line of FIG. 1.

FIG. 3 is an isometric diagram of major sections of the semiconductor device of the first embodiment.

FIG. 4 is a circuit diagram illustrating the configuration of an inverter circuit using the semiconductor device of the first embodiment.

FIG. 5 is a planar diagram of a semiconductor device of a comparative example.

FIG. 6 is a cross-sectional diagram showing the cross section at the B-B′ line of FIG. 5.

FIG. 7 is an isometric diagram of major sections of the semiconductor device of the comparative example.

FIG. 8 is a planar diagram of a semiconductor device according to a second embodiment.

FIG. 9 is a cross-sectional diagram showing the cross section at the C-C′ line of FIG. 8.

FIG. 10 is an isometric diagram of major sections of the semiconductor device of the second embodiment.

FIG. 11 is a planar diagram of a semiconductor device according to a third embodiment.

FIG. 12 is a cross-sectional diagram showing the cross section at the D-D′ line of FIG. 11.

FIG. 13 is an isometric diagram of major sections of the semiconductor device of the third embodiment.

FIG. 14 is a planar diagram of a semiconductor device according to a fourth embodiment.

FIG. 15 is a cross-sectional diagram showing the cross section at the E-E′ line of FIG. 14.

FIG. 16 is an isometric diagram of major sections of the semiconductor device of the fourth embodiment.

FIGS. 17 to 27 are cross-sectional diagrams depicting certain steps associated with the fabrication of the semiconductor device of the first embodiment.

### DETAILED DESCRIPTION

In general, example embodiments will be explained by reference to the figures. In the example embodiments, the first electrical conductivity type material will be N type semiconductor material, and the second electrical conductivity type material will be P type semiconductor material. But this is for example only and in other embodiments the first conductivity type material may be P type and the second conductivity type may be N type without departing from the scope of this disclosure. A semiconductor device with improved recovery characteristics of the diode in a RC-IGBT while maintaining ohmic contact characteristics is provided.

An example embodiment is a semiconductor device having a substrate including: a first electrical conductivity type material; abase layer of a second electrical conductivity type material disposed on one face of the substrate; an anode layer having a higher impurity count in a portion of the base layer; an IGBT region formed on the base layer; a diode region formed adjacent to the IGBT region on the anode layer; a trench reaching from the surface side of the IGBT region and the diode region to the substrate with the area occupied by the trench in the diode region being different from the area occupied in the IGBT region; a drain layer including the second electrical conductivity type material formed on the face of the substrate opposite the IGBT region; and a cathode layer including the first electrical conductivity type material adjacent to the drain layer facing opposite the diode region.

### First Embodiment

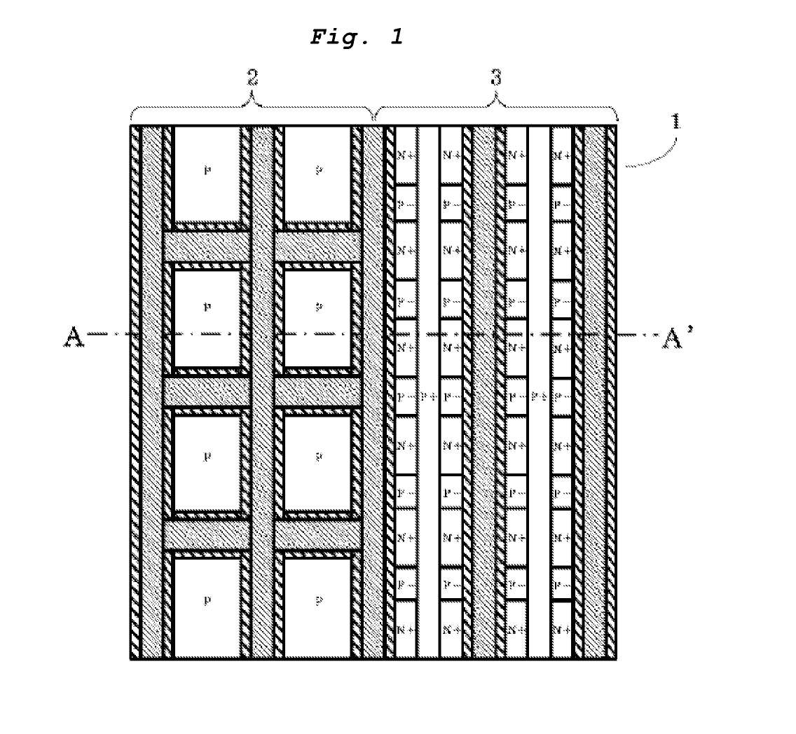

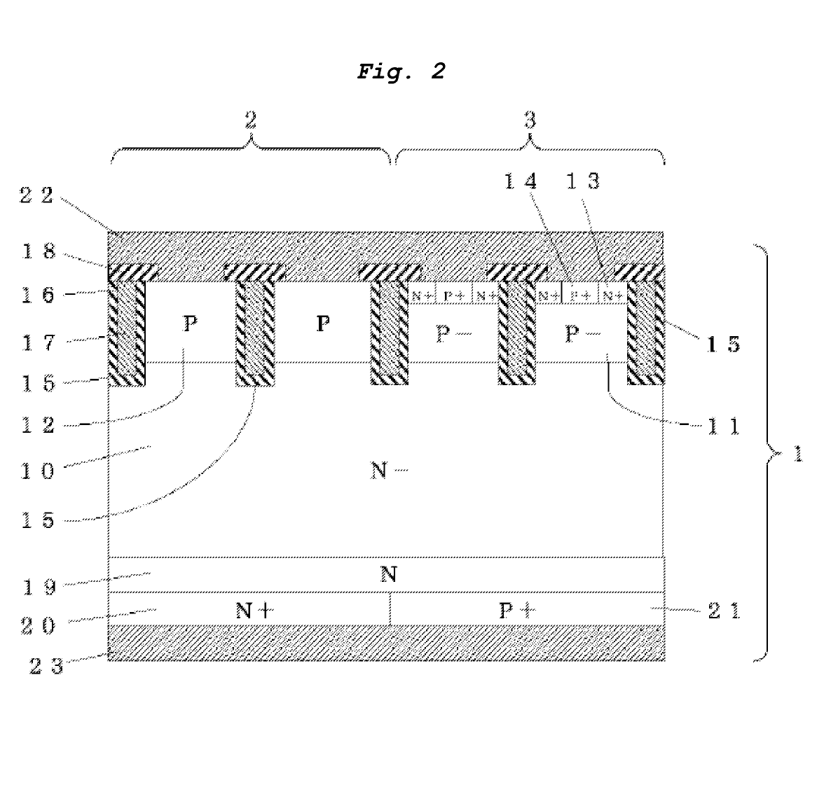

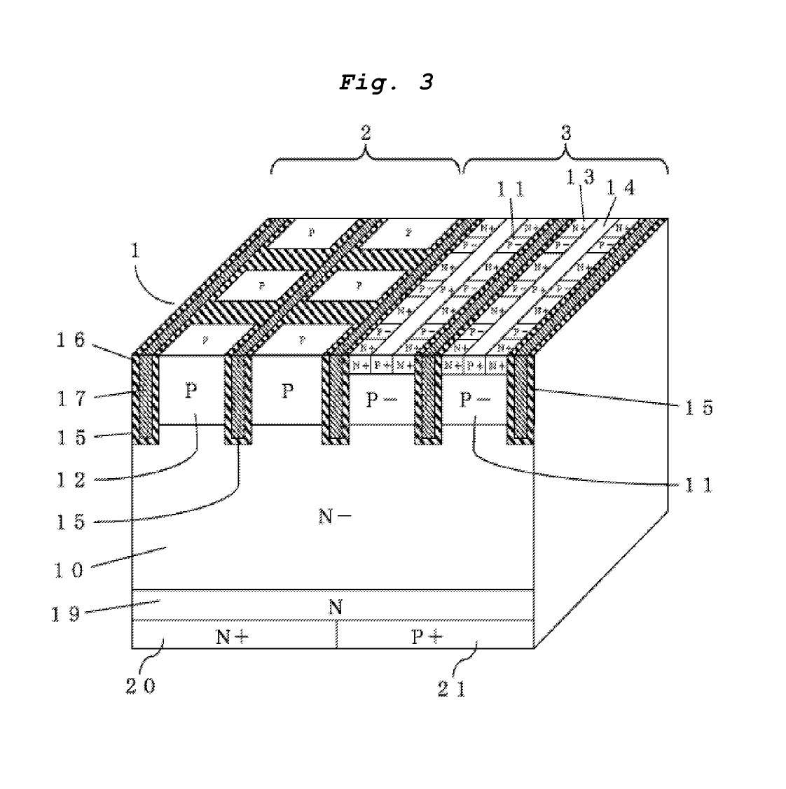

FIG. 1 is a planar diagram showing the structure of semiconductor device 1 according to the first embodiment. Furthermore, FIG. 2 is a cross-sectional diagram showing the cross section at the A-A′ line of FIG. 1. FIG. 3 is an isometric diagram of major sections of the semiconductor device 1.

As shown in FIG. 2 and FIG. 3, semiconductor device 1 is a RC-IGBT which has both a diode 2 and an IGBT region 3 formed jointly, in one body, on the semiconductor substrate.

Semiconductor device 1 has an N⁻ type base substrate 10 as the substrate, and a P type semiconductor region on a top face of the N type base substrate 10. For this P type semiconductor region, a portion is a P⁻ type base layer 11 of IGBT region 3, and a portion is a P type anode layer 12 of diode 2. The P type anode layer 12 has a higher P type impurity concentration than the P⁻ type base layer 11.

The impurity concentration is the impurity amount of per unit volume, represented as molecules (or atoms) per cm⁻³. Impurity concentration is indicative of the ohmic contact characteristics of diode 2.

In the IGBT region 3, the N⁺ type source layer 13 is formed by the injection of an N type impurity into the P type base layer 11. The P⁺ type contact layer 14 within the IGBT region 3 is formed by the injection of a P type impurity into the P⁻ type base layer 11 between the N⁺ type source layers 13.

In accordance with the embodiment depicted in FIG. 1 and FIG. 3, the N⁺ type source layer 13 may be formed by space pulling. This is because, if the effective area of the channel during the action of the IGBT 3 is narrowed, the saturated electric current value is reduced, and device breakdown is prevented.

Furthermore, trenches 15 are disposed in the IGBT region 3. The trenches 15 within or bordering the IGBT region 3 are formed so as to extend past the N⁺ type source layer 13 and the P⁺ type contact layer 14, then past the P⁻ type base layer 11, and into the N⁻ type base substrate 10 below. Trenches 15 within or bordering the diode region 2 are formed so as to extend past the P type anode layer 12 and into the N⁻ type base substrate 10 below. As shown in FIG. 1, as seen from the upper face side, the upper portions of trenches 15 within diode region 2 form a lattice shape. Within trench 15, gate electrode 17 is disposed on gate insulation film 16. The insulation film 18 is disposed on top of gate electrode 17.

On bottom face side (the backside) of the N⁻ type base substrate 10, an N type buffer layer 19 is provided. An N⁺ type cathode layer 20 is disposed in a portion of the backside of N type buffer layer 19 that is beneath diode region 2. Disposed adjacent to the N⁺ type cathode layer 20 is a P⁺ type drain layer 21 of IGBT region 3.

As shown in FIG. 2, a top electrode 22 is disposed so that the P type anode layer 12, the N⁺ type source layer 13, and the P⁺ type contact layer 14 are covered. A bottom electrode 23 is disposed so that the bottom surfaces of the N⁺ type cathode layer 20 and the P⁺ type drain layer 21 are covered with the bottom electrode 23.

In the part of the RC-IGBT device serving as a diode, the N⁺ type cathode layer 20 disposed on the bottom side of the N⁻ type base substrate 10 is utilized as a N+ type cathode region, and the P⁺ type anode layer 12 disposed on the top side of the N⁻ type base substrate 10 is utilized as a P type anode region.

While operating as an IGBT, the P⁺ type drain layer 21 disposed on the bottom side of the N⁻ type base substrate 10 is utilized as a P⁺ drain region. With appropriate arrangement and dimensions of the N⁺ type cathode layer 20 and the P⁺ type drain layer 21 disposed on the bottom side of the N⁻ type base substrate 10, the P⁺ type drain layer 21 can be latched up reliably and the IGBT 3 can be activated.

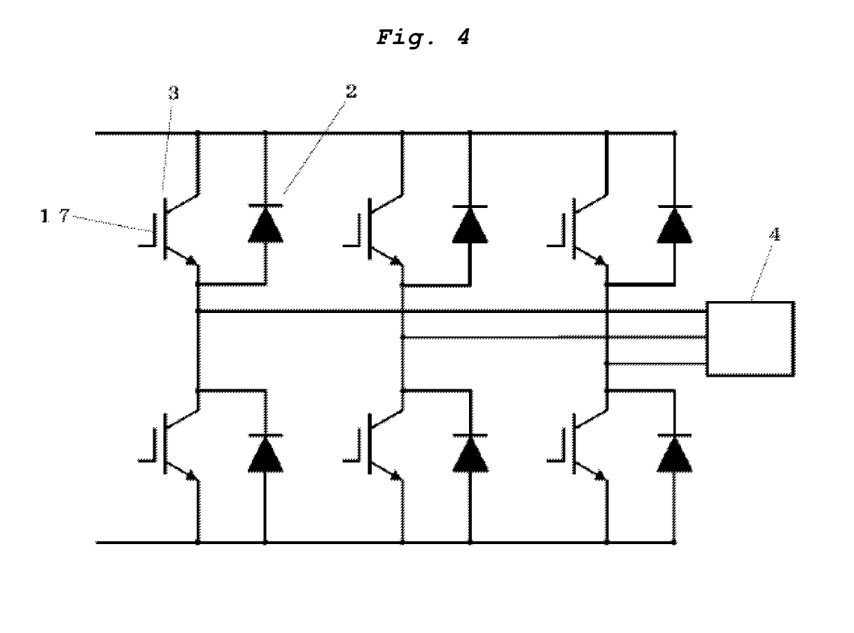

FIG. 4 schematically depicts an inverter circuit for driving a motor 4 formed using the RC-IGBT. As shown in FIG. 4, the diode 2 and the IGBT 3 are connected to act in the following manner:

When the RC-IGBT (of FIG. 2) has a positive bias above a threshold value applied to the gate electrode 17, if the voltage applied to the emitter electrode 22 is smaller than the voltage applied to the collector electrode 23, the IGBT 3 is in the ON state and conduction occurs through the N⁻ type base substrate 10, the P⁻ type base layer 11 and the N⁺ type source layer 13. Since the diode 2 is in reverse bias, it is in the OFF state.

On the other hand, if the voltage applied to the emitter electrode 22 is larger than the voltage applied to the collector electrode 23, the IGBT 3 does not conduct and is in the OFF state. However, diode 2 is now forward biased and, therefore, is in the ON state, which allows electric current to flow from the emitter electrode 22 through the P type anode layer 12 and the N type base substrate 10 to the collector electrode 23.

The emitter electrode 22 and the collector electrode 23 are used in the operation of both the diode 2 and the IGBT 3. When the diode 2 is in the ON state, the associated current flow is in the direction opposite to the current flow when the IGBT 3 is in the ON state. Here, the P type anode layer 12 increases the P type impurity concentration until the emitter electrode 22 and the ohmic contact can take it. In the diode 2 region, the P type anode layer 12 is provided. However, even if the impurity concentration of the P type anode layer 12 is lower than the P⁺ type contact layer of the IGBT 3 region, in order to improve the recovery characteristics of the diode 2 there is a possibility of slightly increasing the concentration.

When the surface contact area between the P type anode layer 12 and the emitter electrode 22 in the diode 2 is very large, the injection of holes from the P type anode layer 12 into N⁻ type base substrate 10 will occur excessively, and the charge carriers in the N⁻ type base substrate 10 will be accumulated excessively. The electric charges accumulated in the N⁻ type base substrate 10 during the reverse recovery action (the recovery action) of the diode are pulled out as a reverse recovery electric current (recovery electric current). This causes an increase in the reverse recovery time (recovery time). Thus, if the upper surface contact area of the P type anode layer 12 in the diode region 2 is made larger the recovery characteristics of the device deteriorate.

Thus, to improve the diode characteristics in the RC-IGBT device, the reduction (suppression) of the impurity levels in the P type anode layer 12 is very important. The impurity level of concern is the amount of the impurity per unit area, represented as molecules per unit surface area (cm⁻²). This impurity level can be used to evaluate the recovery characteristics of the diode 2.

In the present example embodiment, the surface contact area between emitter electrode 22 and the P type anode layer 12 can be adjusted after the formation of the P type anode layer 12 by the formation of trench 15. The surface contact area of the P type anode layer 12 is represented by the surface area occupied by the P type anode layer 12 in top-down planar diagrams (such as in FIG. 1 amongst others) and isometric views (such as in FIG. 3 amongst others).

As shown in FIG. 1 and FIG. 3, trench 15 may be formed so that it is in a lattice shape within diode region 2. The area occupied by trenches 15 may be altered to adjust the surface contract area of the P type anode layer 12. Trenches 15 formed in IGBT region 3 are parallel with trenches 15 formed in diode 2 region. As depicted in FIG. 1, the spacing between trenches is equal in both the diode region 2 and the IGBT region 3, but this is not necessary and the spacing may be adjusted or varied such that the spacing between trenches is not equal. Trench spacing may vary within diode region 2 and may be different than the spacing used in IGBT region 3.

Although the surface contact area of P-type anode layer 12 may be adjusted by narrowing the intervals between trenches 15, there will be process limits on how narrow the intervals between trenches 15 can become before fabrication becomes difficult. The lattice shape of the trenches 15 in the present example provides another means of limiting surface contact area of the P type anode layer 12. The crossing members of the trench lattice provide an additional way to adjust the surface contact area. Rather than just narrowing the trench spacing in a single direction, the spacing and width of the crossing members of the trench lattice can also be adjusted and varied to control surface contract area of P type anode layer 12. Thus by adjusting the surface contact area with trenches 15, the ohmic contact characteristics of the P type anode layer 12 and the emitter electrode 22 are maintained while decreasing the effective impurity level in the P type anode layer.

By adjustment of the two parameters (surface contact area and impurity level of the P type anode layer 12) the ohmic contact characteristics can be maintained without deterioration in the recovery characteristics of the diode 2.

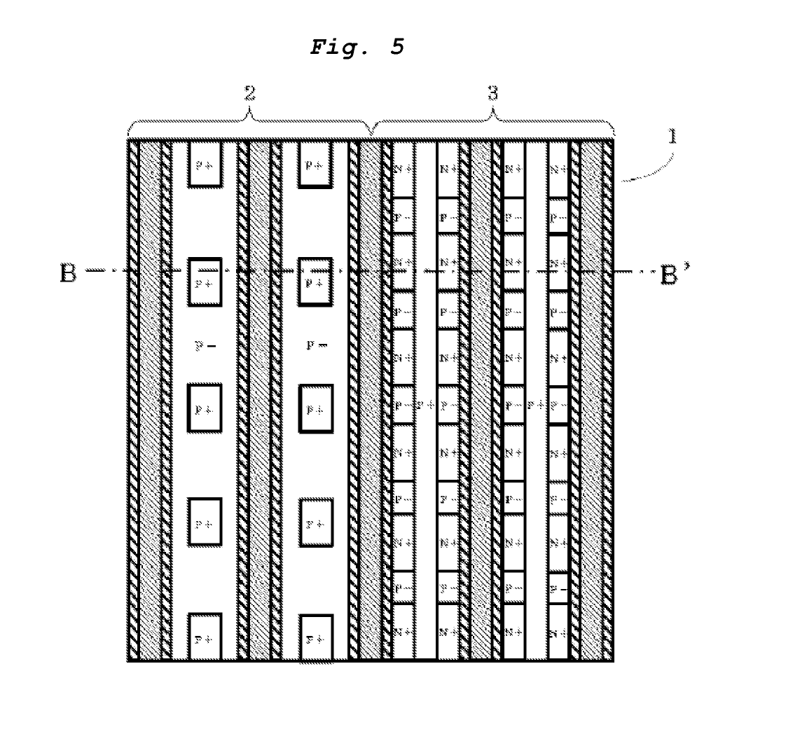

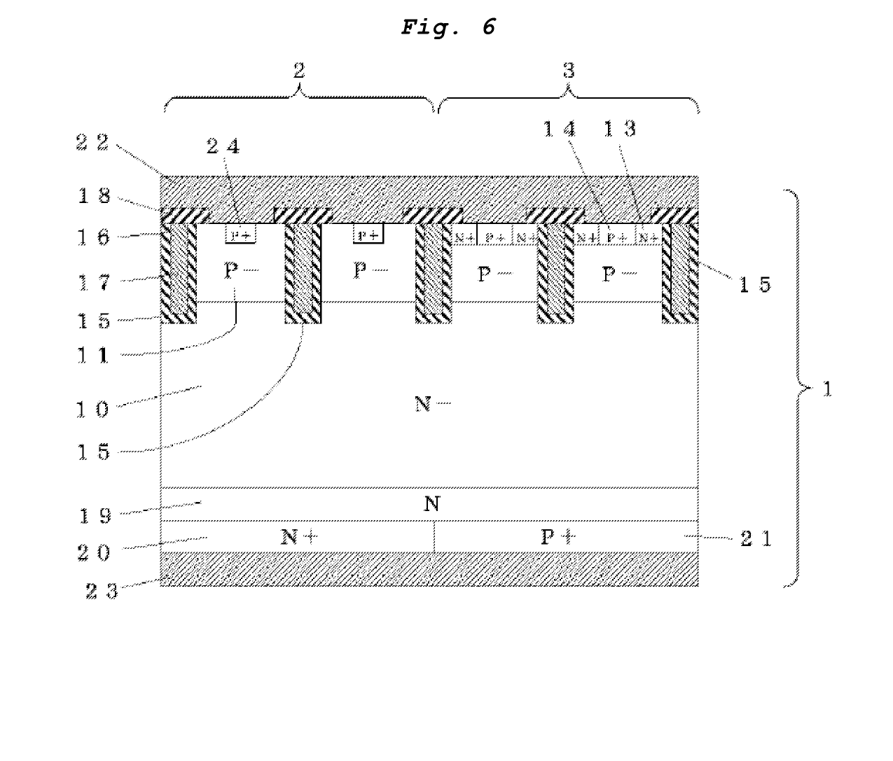

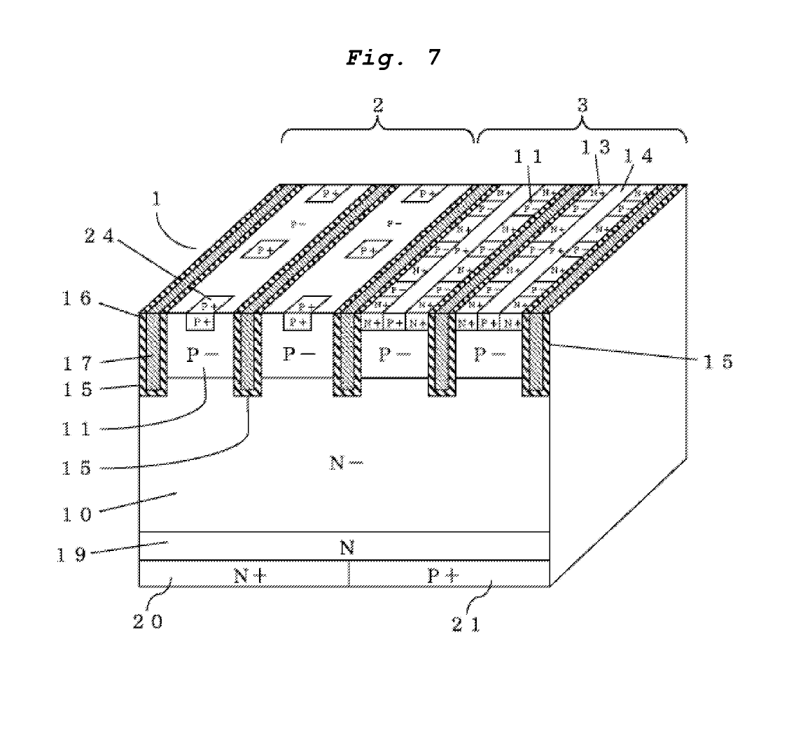

Now a comparative example will be shown to further elucidate the operation of the first example embodiment. FIG. 5 shows the planar diagram of the semiconductor device 1. FIG. 6 is a cross-sectional diagram showing the cross section on the B-B′ line of FIG. 5. FIG. 7 is an isometric diagram of major sections of the semiconductor device 1 showing the comparative example. The same sections as the various sections of the semiconductor device 1 shown in FIGS. 1 to 3 are represented by the same symbols.

This comparative example is an example for the intermittent formation of P⁺ type anode layer 24 by the partial injection of a P type impurity into the P⁻ type base layer 11 of the diode 2 region in order to prevent the deterioration in the recovery characteristics occurring due to an excessively large surface contact area of the P type anode layer 12 and the emitter electrode 22 in the diode 2.

By the partial formation of the P⁺ type anode layer 24 on the P⁻ type base layer 11, the overall impurity level of the anode layer as a whole can be decreased. A lower overall impurity level is tied to an improvement in recovery characteristics. Furthermore, since the P⁺ type anode layer 24 is high in P type impurity concentration of the, ohmic contact with the emitter electrode 22 can be reliably formed, and diode 2 can operate reliably.

However, since the P⁺ type anode layer 24 only partially covers the contact area with emitter electrode 22, the ohmic contact region capable will also be a partial/limited one. This will cause an increase in the local electric current density in the contact region between the P⁺ type anode layer 24 and the emitter electrode 22. There is a possibility the local current density may exceed the breakdown threshold and the device will fail.

Thus, the comparative example shown in FIGS. 5-7 is an example in which an improvement in recovery characteristics is achieved by decreasing the overall impurity level of the anode layer as a whole, while still and reliably achieving ohmic contact between the P⁺ type anode layer 24 and the emitter electrode 22. But with the method of this comparative example, a new problem occurs in that the local electric current density in the contact portion of the P⁺ type anode layer 24 and the emitter electrode 22 is increased.

The first example embodiment provides no P⁺ type anode layer 24 in diode region 2, but rather adjusts contact area by providing the trench 15 in a lattice shape. The ohmic contact characteristics of P type anode layer 12 and emitter electrode 22 are maintained by the adjustment of P type impurity levels in the anode layer, without causing deterioration in recovery characteristics. Furthermore, in the case of the first embodiment, since the surface contact area may be larger than that of the P⁺ type anode layer 24 in the comparative example there is an advantage in that the characteristics of diode 2 can be improved without an accompanying problem with an increase in the local electric current density.

It is also possible to improve diode 2 characteristics by forming a portion of P⁺ type drain layer 21 so that it faces opposite to the diode 2 region. During the action of the diode 2 of the RC-IGBT, because not only the P type anode layer 12 but also the P⁺ type contact layer 14 in IGBT region 3 may possibly function as the anode layer of the diode 2 during the reverse recovery action (recovery action), an increase in the reverse recovery time (recovery time) will occur. Therefore, to prevent deterioration in such recovery characteristics, a portion of the P⁺ type drain layer 21 is provided so that it faces opposite to the diode region 2, and provided so that the P⁺ type contact layer 14 and the N⁺ type cathode layer 20 have increased separation.

In this example, silicon (Si) has been used as the semiconductor substrate. However, embodiments of the present disclosure are not restricted to this material and other semiconductor materials such as silicon carbide (SiC) may be used.

### Second Embodiment

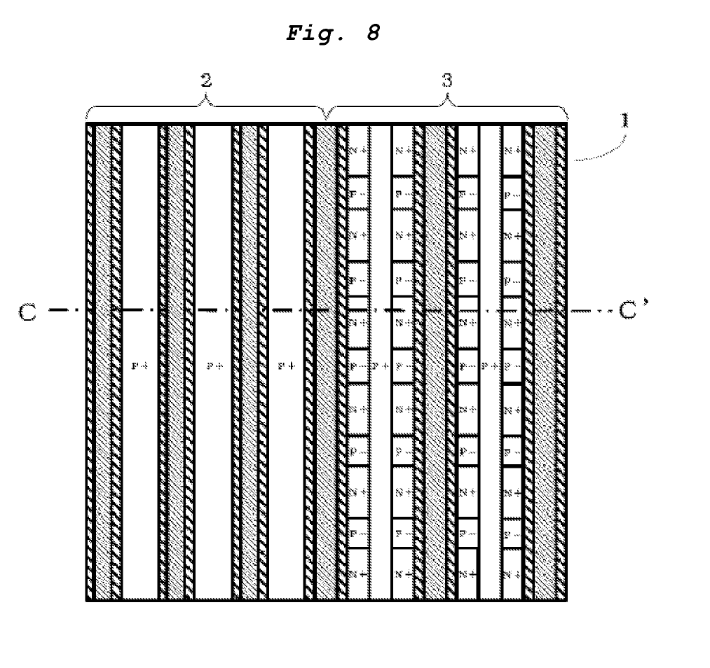

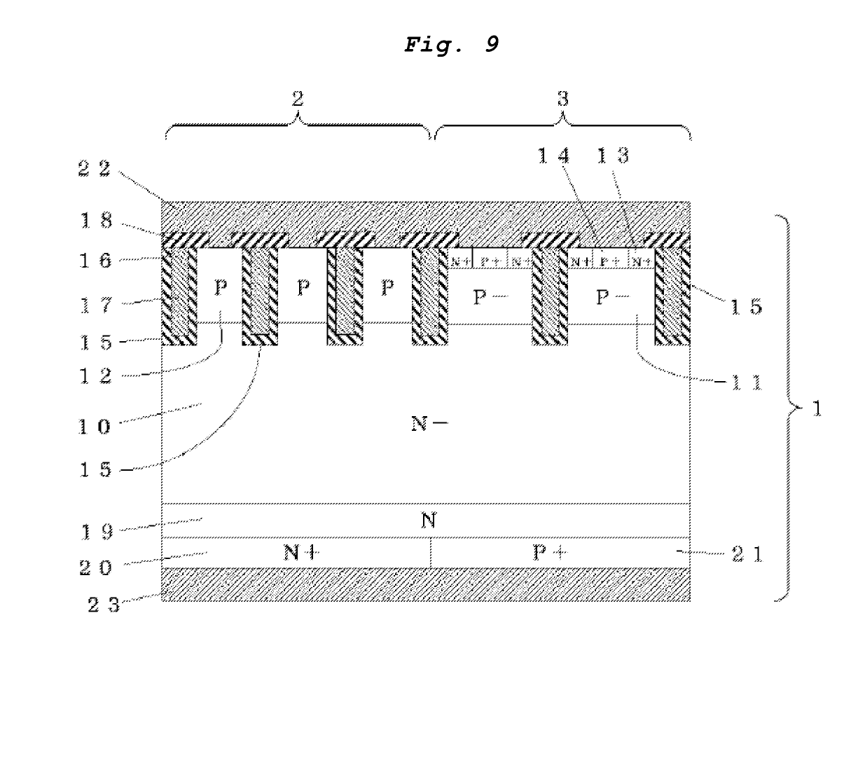

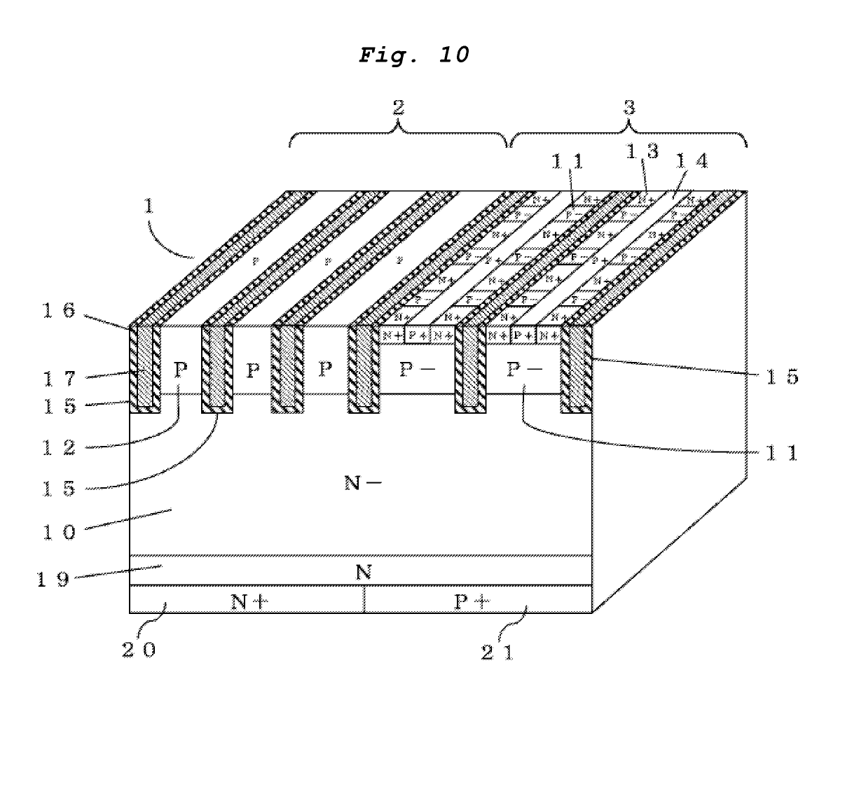

FIG. 8 is a planar diagram showing the structure of the semiconductor device 1 related to a second embodiment. FIG. 9 is a diagram showing the cross section at the C-C′ line of FIG. 8. FIG. 10 is an isometric diagram of the major sections of the semiconductor device 1 related to the second embodiment. In regard to the various depictions of this second embodiment, those device sections corresponding to those of semiconductor device 1 shown in FIGS. 1 through 3 are represented by the same legend symbols.

The second example embodiment that is different from the first embodiment in that trenches 15 are not formed in a lattice shape, but rather are only disposed in parallel (when viewed from the top as in FIG. 8) to N⁺ type source layer 13 and P⁺ type contact layer 14. Thus, in this second embodiment trenches 15 in the diode region 2 and the IGBT region 3 are parallel to one another, but in this example, the interval of the trenches 15 installed in diode region 2 is narrower than the interval of the trenches 15 installed in IGBT region 3.

By narrowing the interval of the trenches 15 in diode region 2, the adjustment of the impurity level in the P type anode layer 12 without causing deterioration in recovery characteristics of diode 2 is made possible. By setting the impurity concentration at level required to make ohmic contact between P type anode layer 12 and emitter electrode 22 and adjusting surface contact area as necessary by varying the interval between trenches 15 in the diode region 2, the recovery characteristics of the diode 2 and the ohmic contact characteristics can both be maintained.

The second example embodiment, like the first example embodiment, can achieve its beneficial results while avoiding the problem of an increasing local electric current density resulting when a P+ type anode layer 24 is used, as in the comparative example.

### Third Embodiment

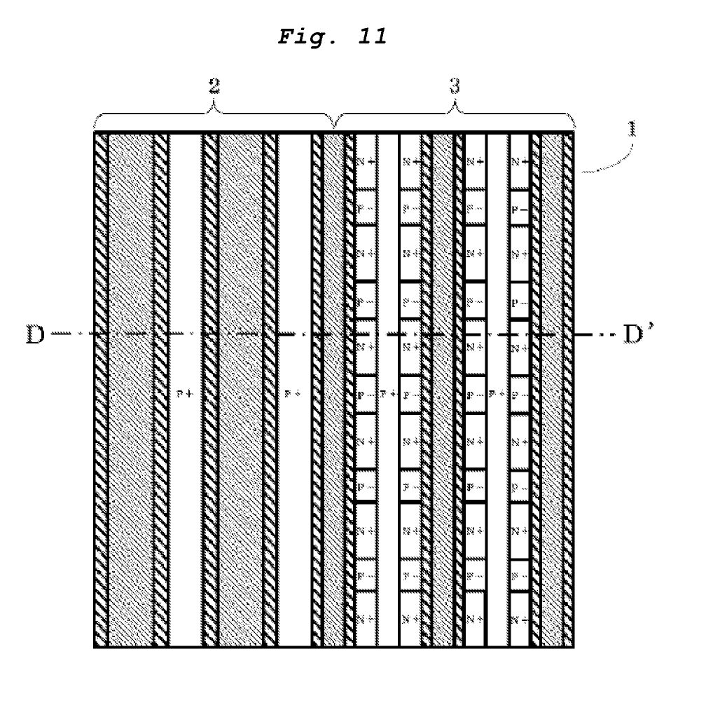

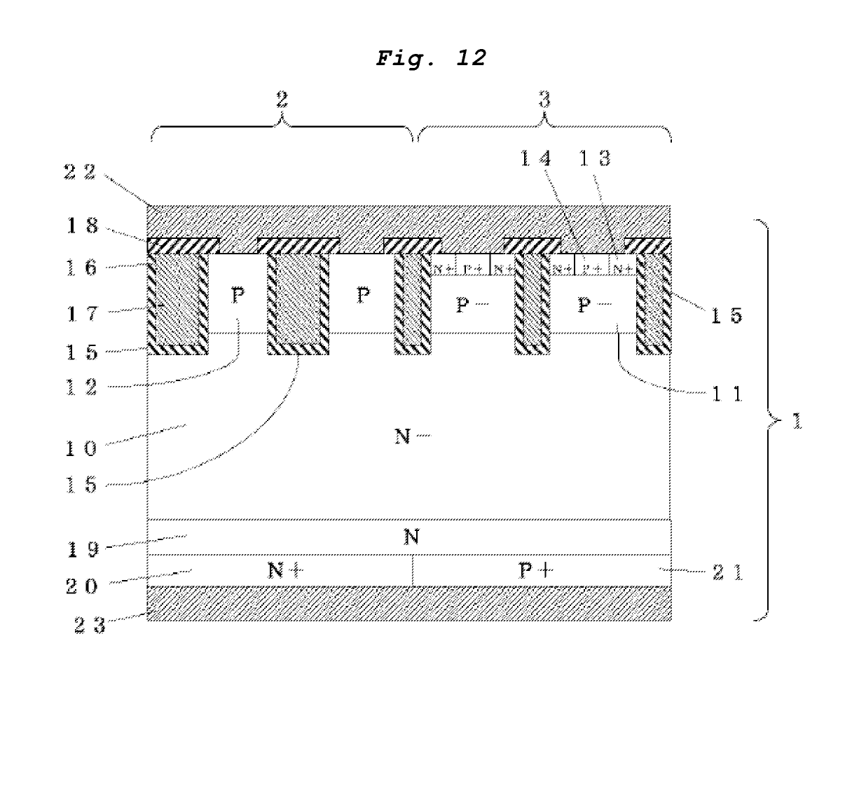

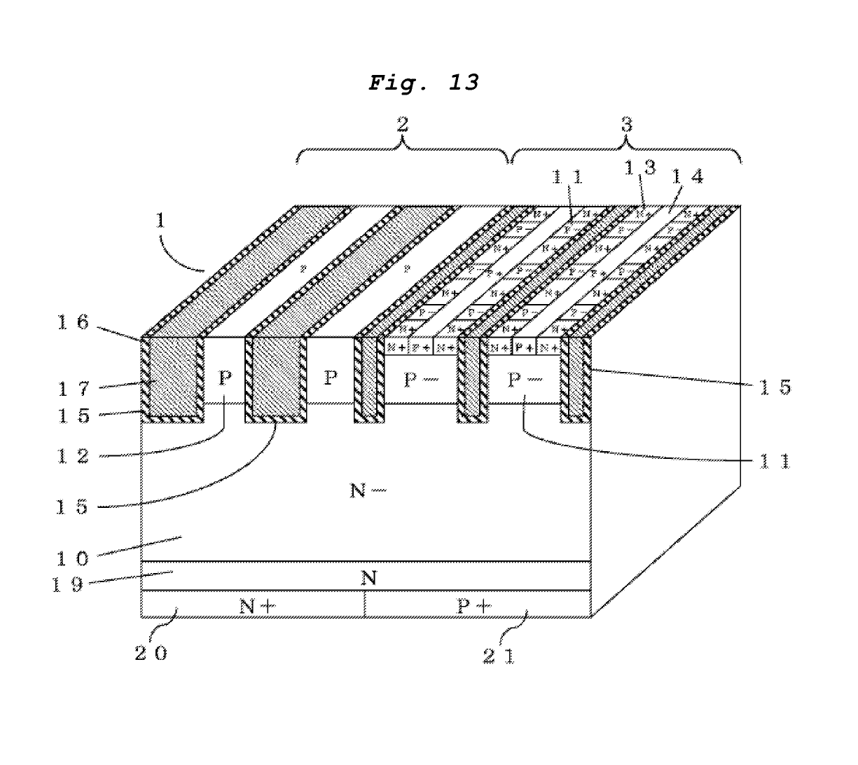

FIG. 11 is a planar diagram showing the structure of the semiconductor device 1 related to a third example embodiment. FIG. 12 is a cross-sectional diagram showing the cross section on the D-D′ line of FIG. 11. FIG. 13 is an isometric diagram of the major sections of semiconductor device 1 related to the third embodiment. In regard to the various depictions of this third embodiment, those device sections corresponding to those of semiconductor device 1 shown in FIGS. 1 through 3 are represented by the same legend symbols.

The third embodiment differs from those of the first and second embodiments in that trenches 15 of the diode region 2 are formed in parallel N⁺ type source layer 13 and P⁺ type contact layer 14 in the same manner as trenches 15 of IGBT region 3, but the width of trenches 15 disposed in the diode region 2 is wider than the trench width of trenches 15 installed in IGBT region 3.

By increasing the trench width of trenches in diode region 2, the contact area of the P type anode layer 12 and the emitter electrode 22 is thereby reduced. The impurity level in P type anode layer 12 can therefore be adjusted to an extent without causing a degrading of the recovery characteristics of diode 2.

The third example embodiment, like the first and second example embodiments, avoids the problem associated with increasing local current density described for the comparative example. By adjusting the trench width and the impurity level in the anode layer, ohmic contact between the anode and emitter can be achieved without causing deterioration in diode 2 recovery characteristics.

### Fourth Embodiment

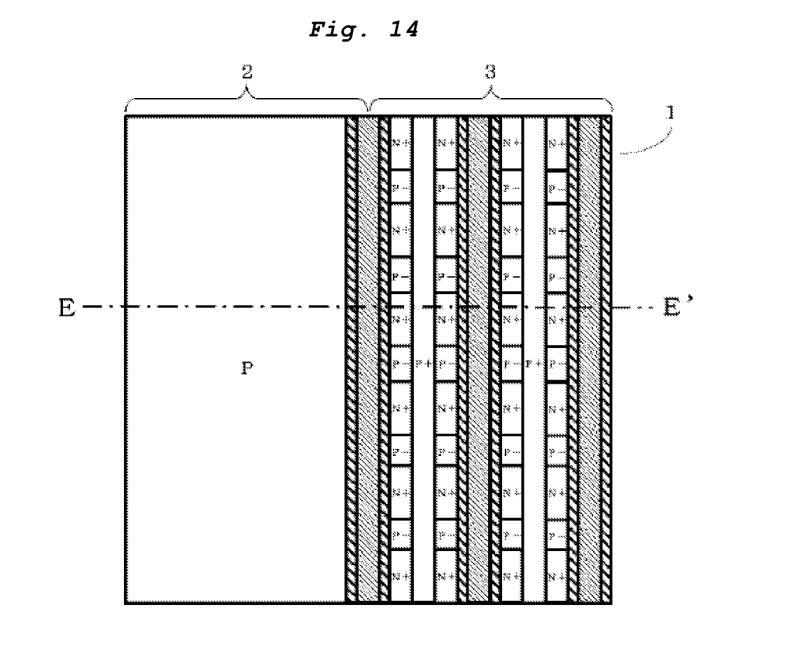

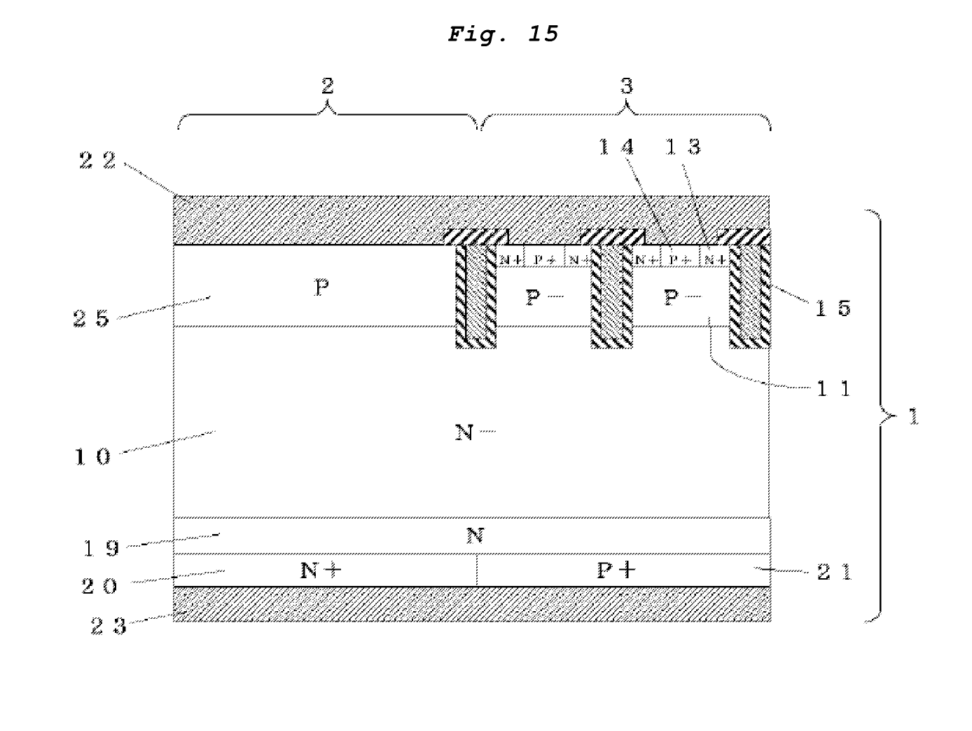

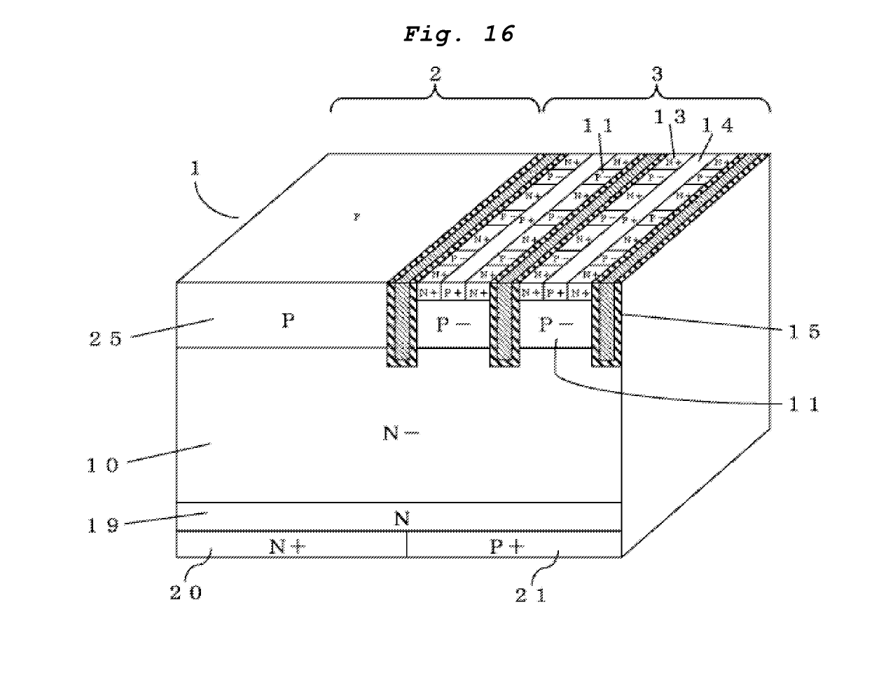

FIG. 14 is a planar diagram showing the structure of the semiconductor device 1 related to a fourth example embodiment. FIG. 15 is a cross-sectional diagram showing the cross section on the E-E′ line of FIG. 14. FIG. 16 is an isometric diagram of the major sections of semiconductor device 1 related to the fourth embodiment. In regard to the various depictions of this forth embodiment, those device sections corresponding to those of semiconductor device 1 shown in FIGS. 1 through 3 are represented by the same legend symbols.

The fourth embodiment differs from those of the first through third embodiments in that there is no trench 15 installed in the P type anode layer 12 of the diode 2.

At this time, the P type anode layer 12 of the diode 2 increases impurity concentration to the extent taken by the emitter electrode 22 and the ohmic contact. However, as described above, if the injection of the holes from the anode occurs excessively, there will be deterioration in the recovery characteristics of diode 2. In the case of the fourth example embodiment the contact area of the anode layer and the emitter electrode 22 is larger than the contact area of the P type anode layer 12 and the emitter electrode 22 in the first through third embodiments because no trench 15 is located within the diode region 2. Therefore, the P type impurity level of the anode layer 25 of the fourth example embodiment must be higher than that of the P⁻ type base layer 11 of IGBT 3. The fact that it is lower than that of the P⁺ type contact layer 14 is the same as the P type anode layer 12 of diode 2 in the first through third embodiments. However, at the impurity level of P type anode layer 12, there would be a possibility of causing deterioration in recovery characteristics.

Therefore, the anode layer 25 in diode 2 of the fourth example embodiment has an impurity level lower than the P type anode layer 12 so deterioration in the recovery characteristics will not occur. P type anode layer 25 is provided to the extent necessary for ohmic contact with emitter electrode 22. Since the contact area of the P type anode layer 25 and the emitter electrode 22 is large, the local increase in the electric current density will not occur and the diode 2 will function appropriately.

In the fourth embodiment, like in the first through third embodiments, the ohmic contact between the P type anode layer 25 and the emitter electrode 22 can be made without the accompanying problem of locally increasing the current density. Furthermore, the impurity total amount of the P type anode layer 25 can be adjusted appropriately without deterioration in recovery characteristics of diode 2.

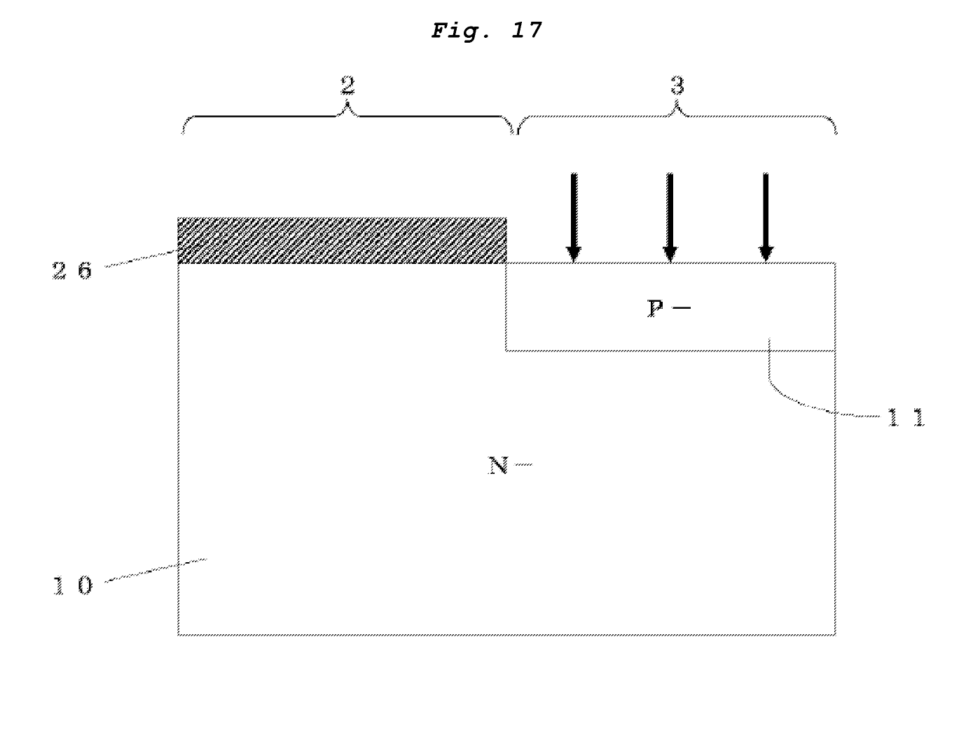

The fabrication process of semiconductor device 1 of the first embodiment will now be explained with reference to FIGS. 17 to 27.

### First Process

FIG. 17 is a cross-sectional diagram after the formation of the P⁻ type base layer 11 only on the portion of the surface of the N⁻ type base substrate 10. On a face of substrate 10, mask 26 is formed using a resist film to mask the region which will be used to form diode region 2. A P type impurity is injected to form the P⁻ type base layer 11 in the IGBT region 3. As the Example P type impurities (dopants) are B (boron) or boron fluoride (BF₂). However, as long as a P type semiconductor can be formed, any other impurity species is also acceptable.

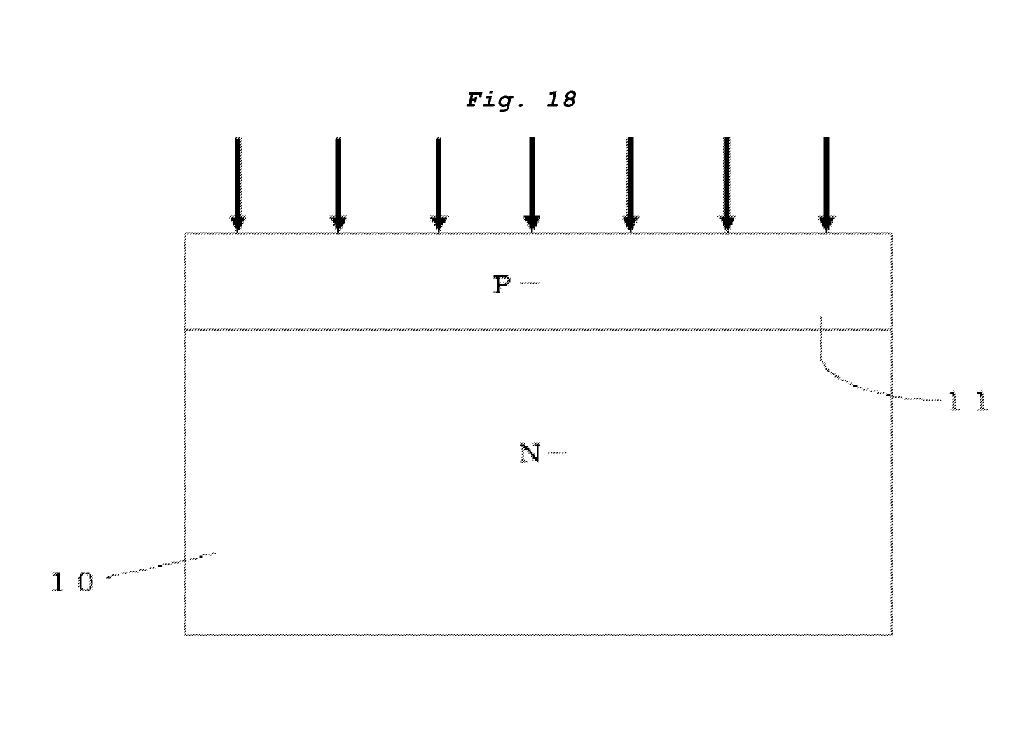

FIG. 18 shows a cross-sectional diagram after the formation of P⁻ type base layer 11 over the whole surface of the N⁻ type base substrate 10. FIG. 18 depicts an acceptable alternative process to the masking process described in relation to FIG. 17.

### Second Process

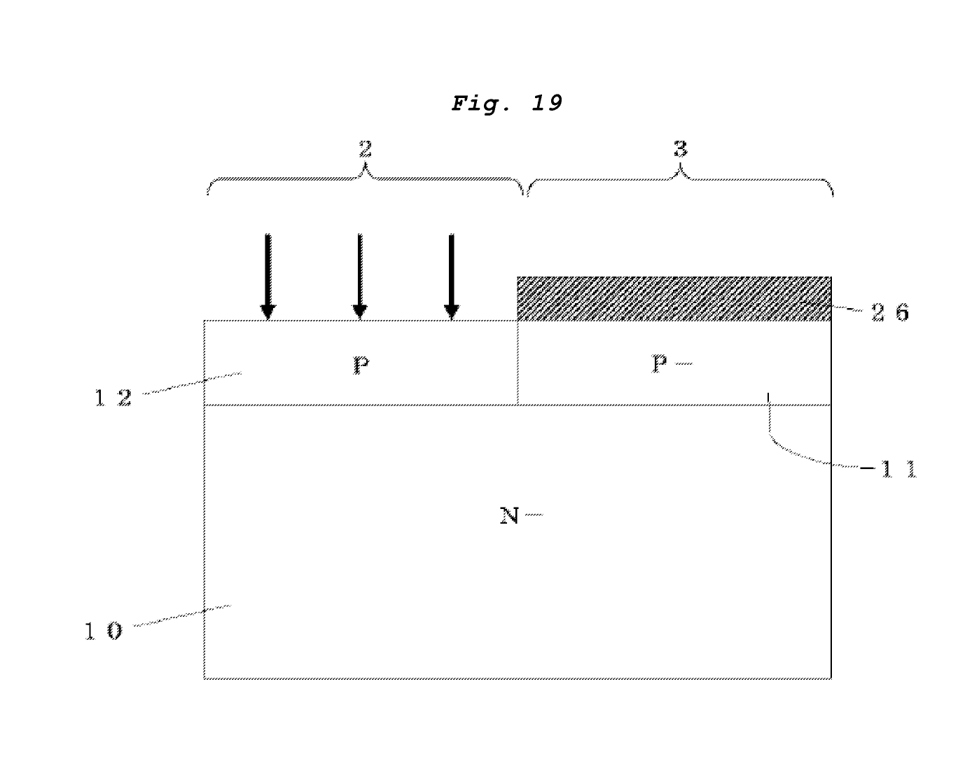

FIG. 19 shows a cross-sectional diagram after the formation of the P type anode layer 12 on the surface of the N⁻ type base substrate 10 in diode region 2. In the second process, mask 26 is formed to cover the region for the formation of the IGBT 3 and the already formed P⁻ type base layer 11 in this region. In the region for the formation of the diode 2, P type impurity is injected to form the P type anode layer 12.

### Third Process

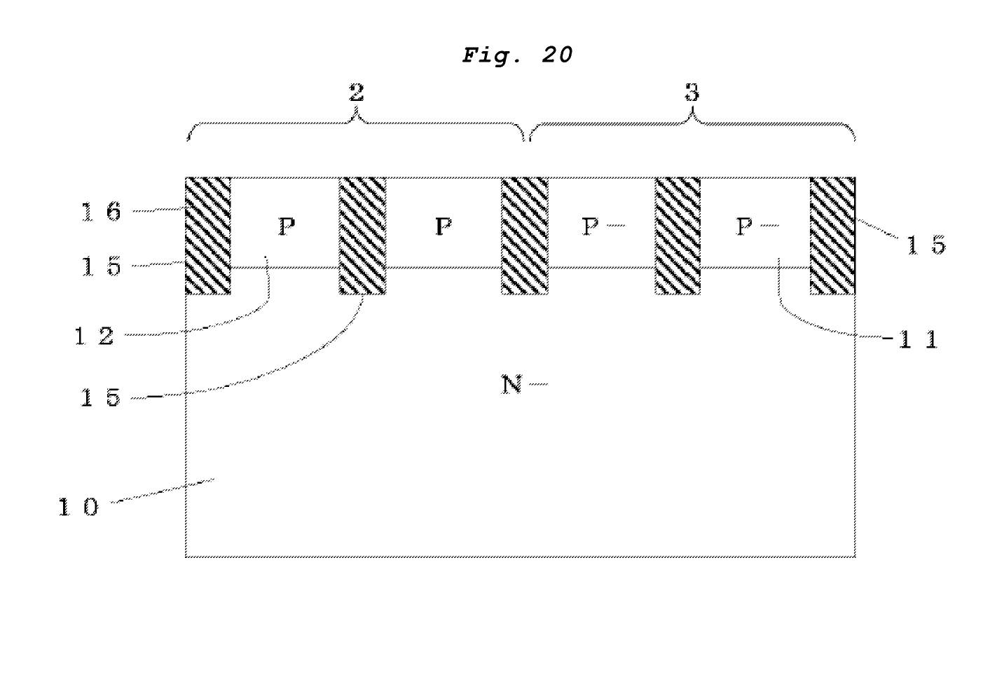

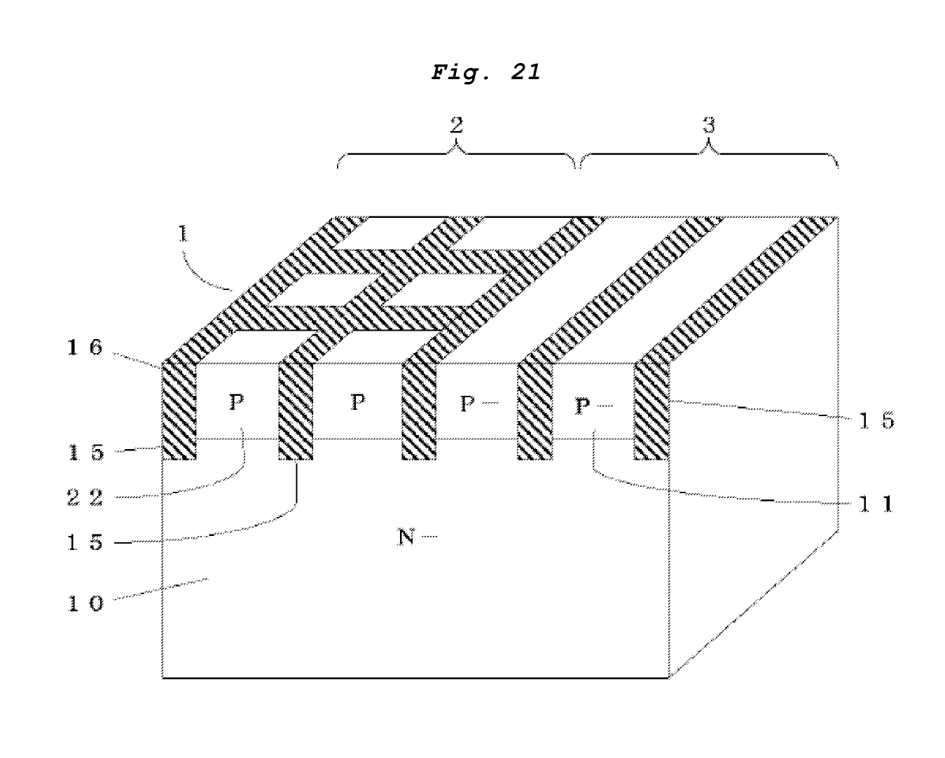

FIG. 20 shows a cross-sectional diagram after the formation of the gate insulation film 16 after the formation of the trench 15. Furthermore, FIG. 21 shows an isometric diagram after the formation of the gate insulation film after the formation of the trench. In the third process, dry etching is used to form trench 15 passing through the P type anode layer 12 and the P⁻ type base layer 11 and reaching the N⁻ type base substrate 10. At this time, as shown in FIG. 21, the trench 15 is formed in a lattice shape as seen from the upper surface. After the trench etch, gate insulation film 16 is formed inside the trench 15.

### Fourth Process

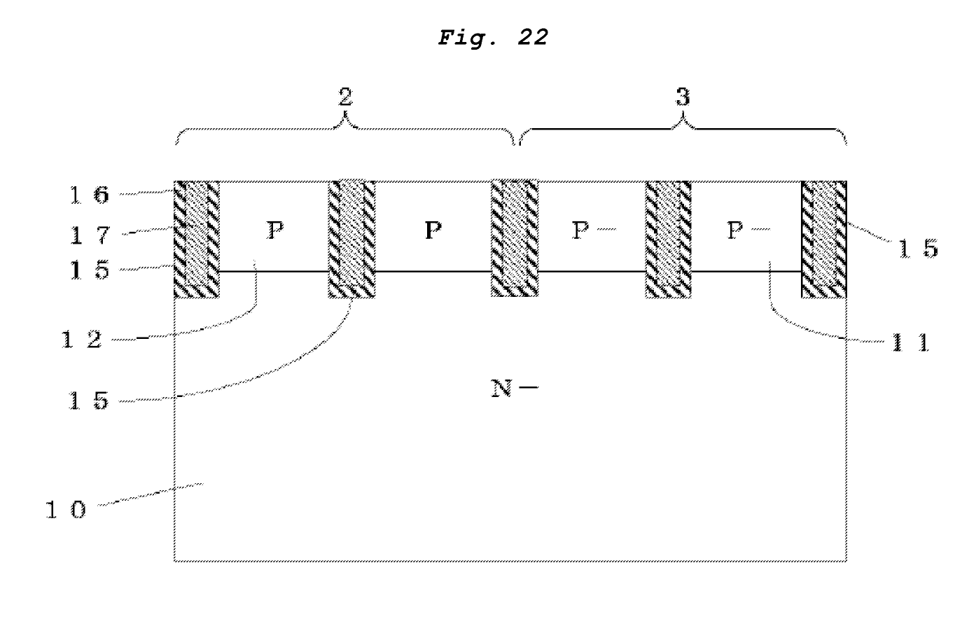

FIG. 22 shows a cross-sectional diagram after the formation of the gate electrode 17, comprised mainly of polysilicon. In the fourth process, as shown in FIG. 22, in the gate insulation film 16 inside the trench 15, the gate electrode 17 is buried.

### Fifth Process

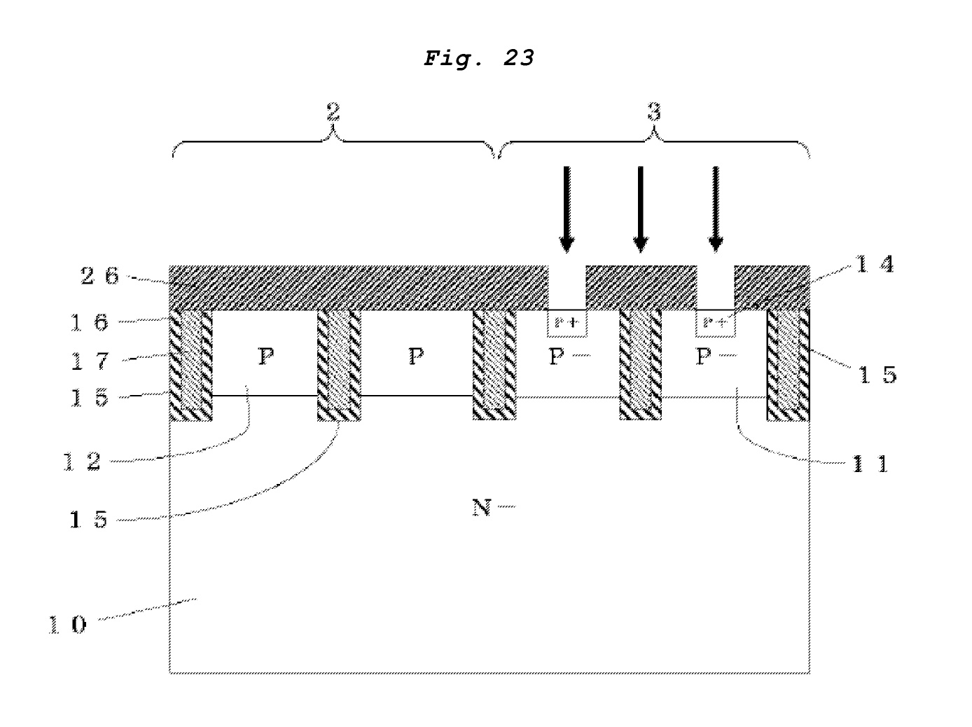

FIG. 23 shows a cross-sectional diagram after the formation of the P⁺ type contact layer 14 in the region of the IGBT 3 on the surface of the N type base substrate 10. In the fifth process mask 26 is formed with a resist, and the P type impurity is injected to form P⁺ type contact layer 14.

### Sixth Process

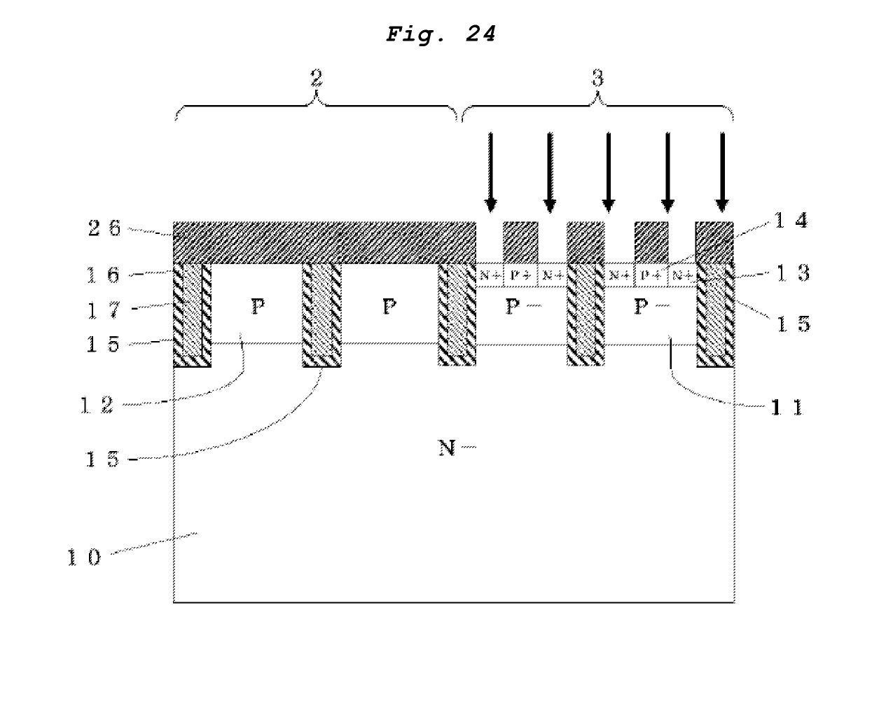

FIG. 24 shows a cross-sectional diagram after the formation of the N⁺ type source layer 13 in the region of the IGBT 3 on the surface of the N⁻ type base substrate 10. In the sixth process, a portion of P⁻ type base layer 11 is injected with an N type impurity to form N⁺ type source layer 13. Examples of N type impurities are, P (phosphorus) or As (arsenic), but as long as the N type semiconductor layer can be formed other N type impurities may be.

### Seventh Process

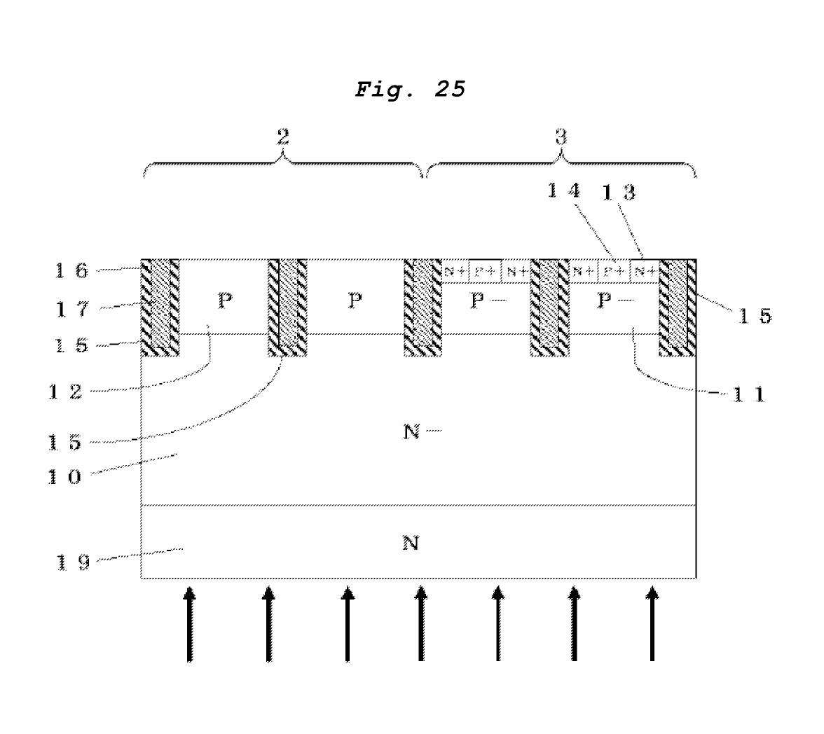

FIG. 25 shows a cross-sectional diagram after the formation of the N type buffer layer 19 and activation by annealing, after polishing of the backside of the N⁻ type base substrate 10. In the seventh process, polishing from the other backside of the N− type base substrate 10 is carried out until the substrate 10 reaches the desired thickness. Afterwards, on the backside of the N⁻ type base substrate 10, an N type impurity is injected to form the N type buffer layer 19. Then, by annealing, (laser annealing or other means) the activation of the backside is carried out.

### Eighth Process

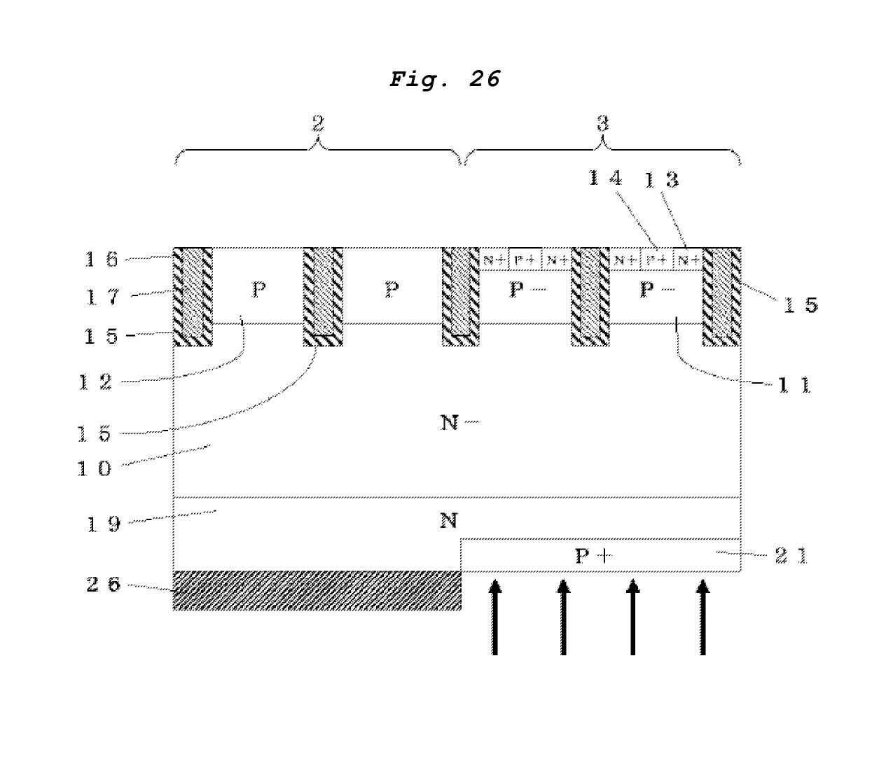

FIG. 26 shows a cross-sectional diagram after the formation of the P⁺ type drain layer 21 on the backside of the N⁻ type base substrate 10. In the eighth process, mask 26 is formed using a resist to cover a portion of the backside of substrate 10 corresponding to diode region 2. P type impurity is injected into N-type buffer layer 19 on the backside of substrate 10 to form P⁺ type drain layer 21.

### Ninth Process

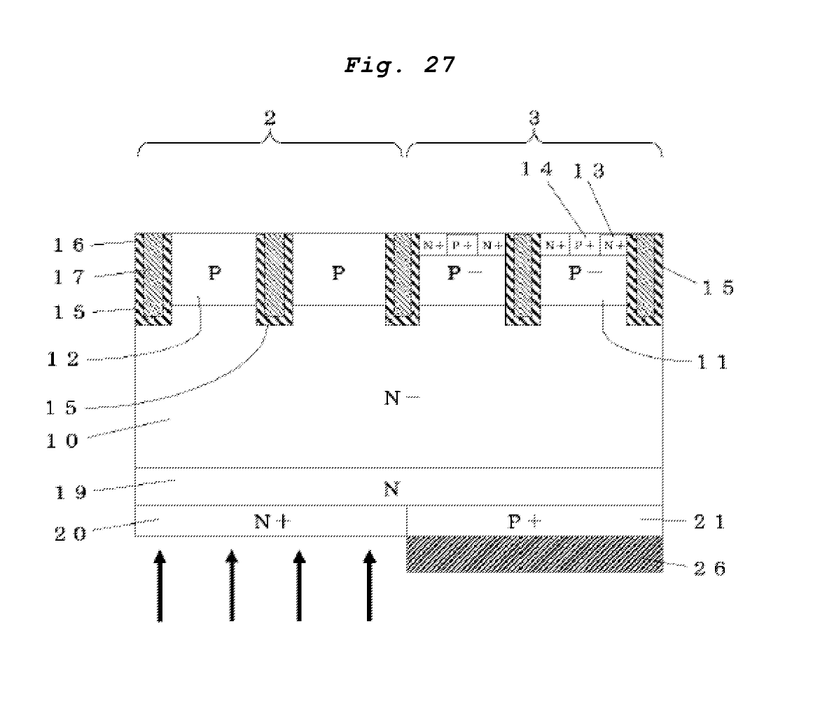

FIG. 27 shows a cross-sectional diagram after the formation of the N⁺ type cathode layer 20 on the backside of the N⁻ type base substrate 10. In the ninth process, mask 26 is formed with a resist to cover the P⁺ type drain layer 21 formed in the eighth process. An N type impurity is injected in to N type buffer layer 19 and the N⁺ type cathode layer 20 is formed.

The activation of the N type buffer layer 19 by annealing, laser annealing or the like, carried out in the seventh process, can also be completed after the ninth process. In this case, the annealing (laser annealing or the other process) related to the seventh process are not required.

Furthermore, the eighth process and the ninth process can also be used for the formation of the N⁺ type cathode layer 20 selectively. After the formation of the N⁺ type cathode layer 20 on the backside as a whole, the P⁺ type drain layer 21 can also be formed selectively.

### Tenth Process

In the tenth process, as shown in FIG. 2, after the formation of insulation film 18 over gate electrode 17, emitter electrode 22 is formed so that P type anode layer 12, N⁺ type source layer 13, P⁺ type contact layer 14, and insulation film 18 are covered.

Collector electrode 23 is formed over N⁺ type cathode layer 20 and P⁺ type drain layer 21 on the back surface side of the N type base substrate 10.

By the above processes, the semiconductor device 1 of the first to third embodiments can be prepared.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor substrate of a first electrical conductivity type, the semiconductor substrate having an upper surface and a bottom surface;
an insulated gate bipolar transistor region formed on the substrate;
a diode region formed adjacent to the insulated gate bipolar transistor region on the substrate;
a base layer of a second electrical conductivity type within the insulated gate bipolar transistor region, the base layer disposed on the upper surface of the substrate;
an anode layer of the second electrical conductivity type within the diode region, the anode layer disposed on the upper surface of the substrate and having a higher impurity level than the base layer; and
a plurality of insulating films extending from the upper surface of the substrate and into the substrate to beneath the base layer and the anode layer, the insulating films being substantially parallel to each other along the upper surface, wherein a spacing between adjacent insulating films in the diode region is less than a spacing between adjacent insulating films in the insulated gate bipolar transistor region.

2. The semiconductor device of claim 1, further comprising:
a collector layer of the second electrical conductivity type disposed on the bottom surface of the substrate, the collector layer being below the base layer; and
a cathode layer of the first electrical conductivity type disposed on the bottom surface of the substrate, the cathode layer being adjacent to the collector layer and beneath the anode layer.

3. The semiconductor device of claim 1, wherein a total area of the upper surface occupied by the plurality insulating films in the diode region is larger than area total area of the upper surface occupied by the plurality of insulating films in the insulated gate bipolar transistor region.

4. The semiconductor device of claim 1, wherein the width of insulating films in the diode region is greater than the width of insulating films in the insulated gate bipolar transistor region.

5. The semiconductor device of claim 1, wherein a portion of the collector layer is disposed below the anode layer in the diode region.

6. The semiconductor device of claim 1, wherein the impurity level in the anode layer provides ohmic contact between the anode layer and an emitter layer disposed on the anode layer.

7. The semiconductor device of claim 1, wherein the anode layer is doped polysilicon.

8. The semiconductor device of claim 1, further comprising a gate electrode disposed within each insulating film in the plurality of insulating films.

9. The semiconductor device of claim 1, wherein the device is operated as a reverse conducting insulated gate bipolar transistor.

10. A semiconductor device, comprising:
a semiconductor substrate of a first electrical conductivity type, the semiconductor substrate having an upper surface and a bottom surface;
an insulated gate bipolar transistor region formed on the substrate;
a diode region formed adjacent to the insulated gate bipolar transistor region on the substrate;
a base layer of a second electrical conductivity type within the insulated gate bipolar transistor region, the base layer disposed on the upper surface of the substrate;
an anode layer of the second electrical conductivity type within the diode region, the anode layer disposed on the upper surface of the substrate and having a higher impurity level than the base layer; and
a plurality of insulating films extending from an upper surface of the base layer or the anode layer into the substrate to below the base layer or anode layer, the plurality of insulating films defining areas where an emitter layer disposed on the base layer and the anode layer contacts the base layer and the anode layer, wherein insulating films in the diode region are parallel to insulating films in the insulated gate bipolar transistor region and spacing between adjacent insulating films in the diode region is different than spacing between adjacent insulating films in the insulated gate bipolar transistor region.

11. The semiconductor device of claim 10, wherein the spacing between adjacent insulating films in the diode region is less than the spacing between adjacent insulating films in the insulated gate bipolar transistor region.

12. A method, comprising:
forming an anode layer of a second conductivity type on an upper surface of a substrate within a diode region of the substrate, the substrate being of a first conductivity type;
forming a base layer of the second conductivity type on the upper surface of the substrate within an insulated gate bipolar transistor region of the substrate;
etching a plurality of trenches through the anode layer and the base layer into the substrate beneath, filling the plurality of trenches with insulating films to control surface area of the anode layer available for contacting an emitter layer disposed over the anode layer; and
depositing the emitter layer over the anode layer and the base layer.

13. The method of claim 12, wherein an impurity level in the anode layer is adjusted to provide ohmic contact between the anode layer and the emitter layer.

14. The method of claim 13, wherein the surface area of the anode layer available for contacting the emitter layer is determined based on the impurity level of the anode layer.

15. The method of claim 12, wherein a spacing between adjacent trenches of the plurality of trenches in the diode region that is different than a spacing between adjacent trenches of the plurality of trenches in the insulated gate bipolar transistor region.
